(19) United States
(12) Patent Application Publication
(10) Pub. No.: US 2007/0298600 A1
(43) Pub. Date: Dec. 27, 2007

(54) Method of Fabricating Semiconductor Device and Semiconductor Device Fabricated Thereby

(76) Inventors: Bong-seok Suh, Gyeonggi-do (KR); Hong-jae Shin, Seoul (KR); Sun-jung Lee, Seoul (KR); Min-chul Sun, Gyeonggi-do (KR); Jung-hoon Lee, Gyeonggi-do (KR)

Correspondence Address: MYERS BIGEL SIBLEY & SAJOVEC, PO BOX 37428, RALEIGH, NC, 27627, US

(21) Appl. No.: 11/425,841

(22) Filed: Jun. 22, 2006

(51) Int. Cl. H01L 21/3205

(52) U.S. Cl. 438/586

(57) ABSTRACT

A method of fabricating a semiconductor device and a semiconductor device fabricated thereby. The method of fabricating the semiconductor device includes forming gate electrodes on a semiconductor substrate; forming source/drain regions within the semiconductor substrate so as to be located at both sides of each of the gate electrodes; forming a nickel silicide layer on surfaces of the gate electrodes and the source/drain regions by evaporating nickel or nickel alloy on the semiconductor substrate formed with the gate electrodes and the source/drain regions and then performing a thermal process on the nickel or the nickel alloy; forming an interlayer insulating layer, which is formed with contact holes through which a surface of the nickel silicide layer is exposed, on a surface obtained after the above processes have been performed; forming an ohmic layer by evaporating a refractory metal conformably along the contact holes, the refractory metal being converted to silicide at a temperature of 500° C. or more; forming a diffusion barrier on the ohmic layer conformably along the contact holes; and forming a metal layer by burying a metal material within the contact holes.

### FIELD OF THE INVENTION

The present invention relates to a method of fabricating a semiconductor device and a semiconductor device fabricated thereby. More particularly, the present invention relates to a method of fabricating a semiconductor device, which is capable of forming a contact having low contact resistance and excellent thermal stability, and a semiconductor device fabricated thereby.

### BACKGROUND OF THE INVENTION

As semiconductor devices become highly integrated, their design rules are rapidly decreasing and their speed is becoming fast. For this reason, processes of forming a silicide layer having very low specific resistance have been developed in order to reduce a sheet resistance and a contact resistance of each of a gate, a source, and a drain of a semiconductor device.

Among the processes, in the case of forming the silicide layer by using cobalt (Co), the cobalt silicide layer may be short-circuited due to agglomeration during a high-temperature rapid thermal process as the line width becomes narrow and the evaporation thickness becomes thin. In addition, pits may be generated at an interface between an active region and a field region due to the thermal hysteresis stress between a cobalt silicide (CoSiₓ) layer and a nitride layer, or the cobalt silicide layer and a silicon oxide layer during the high-temperature rapid thermal process. For this reason, the silicide layer is formed by using nickel (Ni) so as to eliminate defects generated in the cobalt silicide layer.

Further, contacts for making electrical connections between the active regions and wiring lines or between the wiring lines are formed on the silicide layer. The contacts can be formed by forming contact holes, through which the silicide layer is exposed, on an interlayer insulating layer, forming an ohmic layer and a diffusion barrier, and burying a metal material.

However, when the ohmic layer made of titanium (Ti) is formed on the nickel silicide layer, titanium may diffuse at a low temperature, which causes the ohmic layer to react with the nickel silicide layer As a result, the nickel silicide layer may be damaged, and accordingly, the reliability of the semiconductor device may be lowered.

### SUMMARY OF THE INVENTION

It is an object of the present invention to provide a method of fabricating a semiconductor device, which is capable of forming a contact having low contact resistance and excellent thermial stability.

Further, it is another object of the present invention to provide a semiconductor device fabricated by the method described above.

Furthermore, objects of the present invention are not limited to those mentioned above, and other objects of the present invention will be apparently understood by those skilled in the art through the following description.

In order to achieve the above objects, according to an aspect of the invention, a method of fabricating a semiconductor device includes forming gate electrodes on a semiconductor substrate; forming source/drain regions within the semiconductor substrate so as to be located at both sides of each of the gate electrodes; forming a nickel silicide layer on surfaces of the gate electrodes and the source/drain regions by evaporating nickel or nickel alloy on the semiconductor substrate formed with the gate electrodes and the source/drain regions and then performing a thermal process on the nickel or the nickel alloy; forming an interlayer insulating layer, which is formed with contact holes through which a surface of the nickel silicide layer is exposed, on a surface obtained after the above processes have been performed; forming an ohmic layer by evaporating a refractory metal conformably along the contact holes, the refractory metal being converted to silicide at a temperature of 500° C. or more; forming a diffusion barrier on the ohmic layer conformably along the contact holes; and forming a metal layer by burying a metal material within the contact holes.

Further, according to another aspect of the invention, a semiconductor device includes gate electrodes formed on a semiconductor substrate; source/drain regions formed within the semiconductor substrate so as to be located at both sides of each of the gate electrodes; a nickel silicide layer formed on surfaces of the gate electrodes and the source/drain regions; an interlayer insulating layer formed with contact holes through which a surface of the nickel silicide layer is exposed; an ohmic layer which is formed conformably along the contact holes and is made of a refractory metal being converted to silicide at a temperature of 500° C. or more; a diffusion barrier formed on the ohmic layer conformably along the contact holes; and a metal layer buried within the contact holes.

### BRIEF DESCRIPTION OF THE DRAWINGS

The above and other features and advantages of the present invention will become more apparent by describing, in detail, preferred embodiments thereof with reference to the attached drawings in which:

FIG. 1 is a cross-sectional view illustrating a semiconductor device according to an embodiment of the present embodiment;

FIG. 2 is a flow chart explaining a method of fabricating a semiconductor device according to the embodiment of the invention;

FIG. 3 is a view illustrating a procedure of the method of fabricating the semiconductor device according to the embodiment of the invention;

FIG. 4 is a view illustrating a procedure of the method of fabricating the semiconductor device according to the embodiment of the invention;

FIG. 5 is a view illustrating a procedure of the method of fabricating the semiconductor device according to the embodiment of the invention;

FIG. 6 is a view illustrating a procedure of the method of fabricating the semiconductor device according to the embodiment of the invention; and

FIG. 7 is a view illustrating a procedure of the method of fabricating the semiconductor device according to the embodiment of the invention.

### DESCRIPTION OF THE PREFERRED EMBODIMENTS

Advantages and features of the present invention and methods of accomplishing the same may be understood more readily by reference to the following detailed description of preferred embodiments and the accompanying drawings. The present invention may, however, be embodied in many different forms and should not be construed as being limited to the embodiments set forth herein. Rather, these embodiments are provided so that this disclosure will be thorough and complete and will fully convey the concept of the invention to those skilled in the art, and the present invention will only be defined by the appended claims. Like reference numerals refer to like elements throughout the specification.

The present invention will now be described more fully with reference to the accompanying drawings, in which preferred embodiments of the invention are shown.

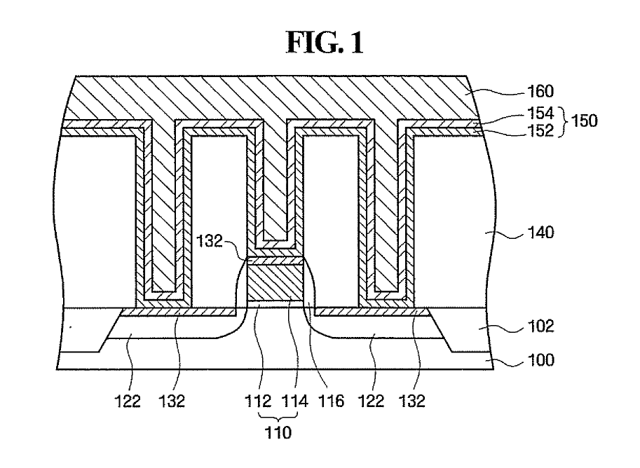

First, a semiconductor device according to the embodiment of the present invention will be described in detail with reference to FIG. 1. FIG. 1 is a cross-sectional view illustrating the semiconductor device according to the embodiment of the present invention.

As shown in FIG. 1, a semiconductor substrate 100 is separated into a field region and an active region by means of an element separation layer 102, and a gate electrode 110 is located on the active region. The gate electrode 110 located on the semiconductor substrate 100 includes a gate insulating layer 112 and a conductive layer 114 for gate electrodes stacked on the gate insulating layer 112, and spacers 116 are formed on both sides of the gate electrode 110. In addition, source/drain regions 122 into which impurity ions are injected are formed within the semiconductor substrate 100 on both the sides of the gate electrode 110. In addition, on the surfaces of the gate electrode 110 and the source/drain regions 122, a nickel silicide layer 132 is formed so as to reduce the resistance at the time of forming a contact hole 142.

Further, an interlayer insulating layer 140 is located on the semiconductor substrate 100. On the interlayer insulating layer 140, contact holes 142 through which the nickel silicide layer 132 formed on the surfaces of the gate electrode 110 and the source/drain regions 122 is exposed are formed.

Furthermore, a barrier 150 is conformably formed along a surface of the interlayer insulating layer 140 with the contact holes 142 formed therein. At this time, the barrier 150 includes an ohmic layer 152 and a diffusion barrier 154, and the ohmic layer 152 being in contact with the nickel silicide layer 132 is made of a refractory metal, which is converted to silicide at a temperature of 500° C. or more, in order to improve the thermal stability. As the refractory metal, Ta, Hf, W, Mo, or V can be used, for example.

In addition, the diffusion barrier 154 on the ohmic layer 152 is made of, for example, TiN, TaN, or Wn and serves to prevent a metal material, for filling the contact holes 142, from diffusing. In addition, for example, W, Cu, or Al may be used as the metal material for filling the contact holes 142.

Hereinafter, a method of fabricating a semiconductor device according to the embodiment of the present invention will be described in detail with reference to FIGS. 1 to 7.

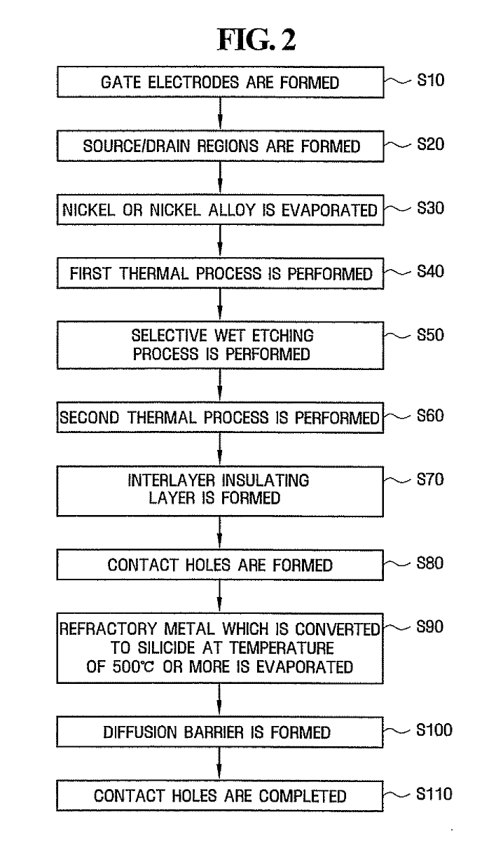

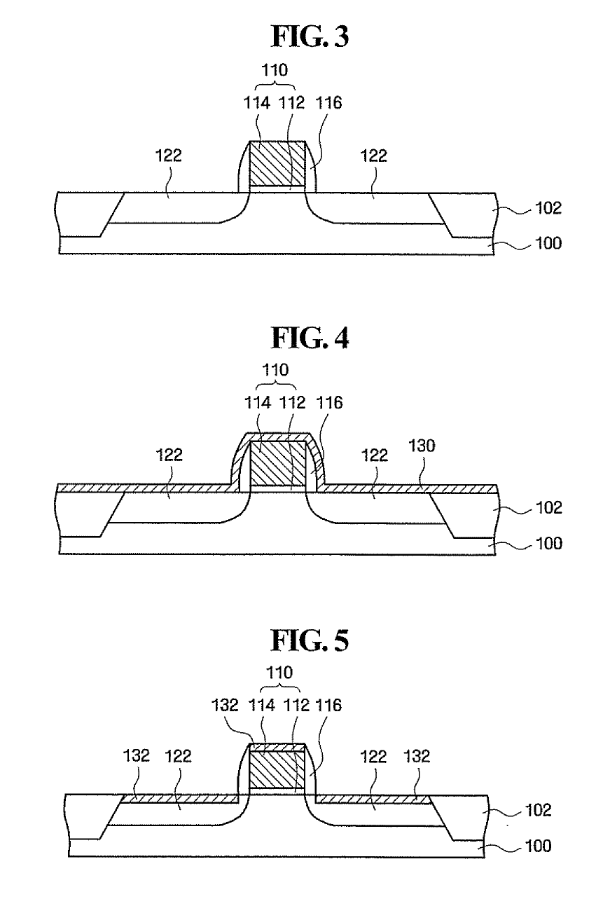

FIG. 2 is a flow chart explaining a method of fabricating a semiconductor device according to the embodiment of the invention. FIGS. 3 to 7 are views illustrating procedures of the method of fabricating the semiconductor device according to the embodiment of the invention.

First, as shown in FIGS. 2 and 3, the element separation layer 102 for separating the active region and the field region from each other is formed on the semiconductor substrate 100. The element separation layer 102 can be formed by using a LOCOS (Local Oxidation of Silicon) method or an STI (Shallow Trench Isolation) method.

Thereafter, the gate electrodes 110 are formed on the active region of the semiconductor substrate 100 (S10). The gate electrodes 110 can be formed by sequentially stacking the gate insulating layer 112 and the conductive layer 114 for gate electrodes on the semiconductor substrate 100 and then patterning the stacked gate insulating layer 112 and conductive layer 114. At this time, the gate insulating layer 112 may be formed of an oxide film, and the conductive layer 114 for gate electrodes may be formed of a polysilicon film doped with impurities.

Then, the spacers 116 are formed on both the sides of the gate electrode 110 by evaporating an insulating layer for spacers on an entire surface of the semiconductor substrate 100 and then by performing an anisotropic etching process on the insulating layer. At this time, the insulating layer for spacers may be formed of a silicon nitride film.

Subsequently, impurities are ion-implanted into the semiconductor substrate 100 by using the gate electrodes 110, the spacers 116, and the element separation layer 102 as an ion implantation mask. As a result, the source/drain regions 122 are formed within the semiconductor substrate 100 so as to be located at both the sides of each of the gate electrodes 110 (S20). The gate electrodes 110, the spacers, and the source/drain regions 122 form a MOS (metal oxide silicon) transistor.

Then, the semiconductor substrate 100 on which the source/drain regions 122 are formed is subjected to a thermal process so as to activate the impurities within the source/drain regions 122. Then, a surface of the semiconductor substrate 100 on which the gate electrodes 110 and the source/drain regions 122 are formed is pre-cleaned cleaned so as to remove a natural oxide layer, particles, or the like remaining on the surface of the semiconductor substrate 100.

Thereafter, as shown in FIGS. 2 and 4, a metal silicide layer 160 is formed on the entire surface of the semiconductor substrate 100 formed with the gate electrodes 110 and the source/drain regions 122 (S30). At this time, the metal silicide layer 160 is formed by evaporating nickel (Ni) or nickel alloy (Ni-alloy), and the nickel alloy may include any one selected from the group consisting of Ta, Zr, Ti, Hf, W, Co, Pt, Pd, V, Nb, and Re in an amount of 20 at % (atomic %) or less with respect to the nickel.

Then, as shown in FIGS. 2 and 5, a first thermal process is performed on the entire surface of the semiconductor substrate 100 (S40). The first thermal process is performed at a temperature of approximately 300 to 380° C., and the silicide layer 132 is formed at a portion where the metal silicide layer 160 and silicon come into contact with each other. That is, since nickel and silicon react with each other, the nickel silicide layer 132 is formed on the surfaces of the gate electrodes 110 and the source/drain regions 122. The thermal process of forming the nickel silicide layer 132 may be performed by using a rapid thermal process (RTP) apparatus, a furnace, or a sputtering apparatus.

After the nickel silicide layer 132 is formed, a selective wet etching process is performed so as to remove nickel or nickel alloy, which has not reacted with silicon (S50). At this time, a solution made by mixing sulphuric acid (H₂SO₄) and hydrogen peroxide (H₂O₂) may be used as a wet etching solution.

Then, a second thermal process is performed on the entire surface of the semiconductor substrate 100 so as to form the nickel silicide layer 132 having excellent thermal stability (S60). The second thermal process is performed at a temperature of approximately 400 to 500° C., which is a temperature higher than the first thermal process.

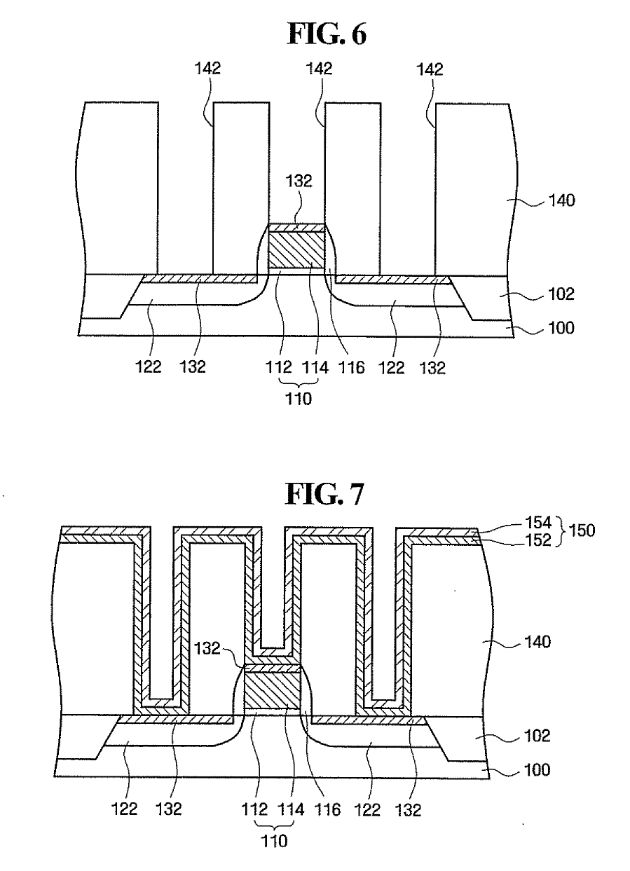

Thereafter, as shown in FIGS. 2 and 6, the interlayer insulating layer 140 having sufficient thickness is formed on the semiconductor substrate 100 (S70). At this time, the interlayer insulating layer 140 may be made of silicon oxide, such as BSG (BoroSilicate Glass), PSG (PhosphoSilicate Glass), BPSG (BoroPhosphoSilicate Glass), or USG JUndoped silicate Glass). Then, a photoresist pattern (not shown) for forming the contact holes 142 is formed on the interlayer insulating layer 140. Then, by using the photoresist pattern as an etching mask, the contact holes 142 are formed until the silicide layer 132 is exposed (S80). That is, through the contact holes 142, a surface of the nickel silicide layer 132 on the gate electrodes 110 and the source/drain regions 122 is exposed.

Subsequently, as shown in FIGS. 2 and 7, the barrier 150 is formed by sequentially stacking the ohmic layer 152 and the diffusion barrier 154 conformably along the contact holes 142. More specifically, the ohmic layer 152 is first formed so as to improve the adhesion of the metal layer 160, which is buried within the contact holes 142 at the time of forming the contacts (S90). At this time, since the ohmic layer 152 comes into contact with the nickel silicide layer 132 located therebelow, the ohmic layer 152 is made of a material that does not react with the nickel silicide layer 132 by considering the subsequent processes. That is, since the subsequent processes of forming the diffusion barrier 154, the metal layer 160, a passivation layer (not shown), and the like are performed at a temperature of approximately 500° C. or less, the ohmic layer 152 is formed by using a refractory metal, which reacts with silicon at a temperature of approximately 500° C. or more so as to be converted to silicide. For example, the ohmic layer 152 may be formed by using Ta, Hf, W, Mo, or V.

Specifically, since the ohmic layer 152 is not converted to silicide as long as the subsequent processes are performed at a temperature of approximately 500° C. or less, it is possible to prevent the nickel silicide layer 132 from being damaged due to the reaction between silicon and a metal material included in the ohmic layer 152.

In addition, the ohmic layer 152 may be conformably formed along the contact holes 142 by performing an evaporation process, such as a PVD (physical vapor deposition) process, a CVD (chemical vapor deposition) process, or an ALD (atomic layer deposition) process.

In the embodiment of the invention, even though the refractory metal converted to silicide at a temperature of 500° C. or more has been used, the refractory metal can be selected depending on the temperature in the subsequent processes.

As such, since it is possible to prevent the metal material included in the ohmic layer 152 from reacting with the nickel silicide layer 132 located below the ohmic layer 152 during the subsequent processes, it is possible to form a contact having a low contact resistance and excellent thermal stability.

Then, the diffusion barrier 154 is conformably formed on the ohmic layer 152 (S100). The diffusion barrier 154 serves to prevent that the metal material for filling the contact holes 142 diffuses and then reacts with the silicon. The diffusion barrier 154 can be made of, for example, TiN, TaN, or WN by using a CVD method.

Then, a metal material is buried within the contact holes 142 on which the barrier 150 is formed, thereby completing the contact as shown in FIG. 1 (S110). At this time, the metal layer 160 that is buried within the contact holes 142 can be made of, for example, W, Cu, or Al by using an evaporation process, such as a PVD process, a CVD process, or an ALD process.

Although the present invention has been described in connection with the exemplary embodiments of the present invention, it will be apparent to those skilled in the art that various modifications and changes may be made thereto without departing from the scope and spirit of the invention. Therefore, it should be understood that the above embodiments are not limitative, but illustrative in all aspects.

As describe above, according to the method of fabricating the semiconductor device and the semiconductor device fabricated thereby of the invention, since the ohmic layer is made of a refractory metal which is converted to silicide at a temperature of approximately 500° C. or more, it is possible to prevent the ohmic layer and the nickel silicide layer from reacting with each other during the subsequent processes performed at a temperature of approximately 500° C. or less.

That is, since the ohmic layer is formed by using the refractory metal, which is converted to silicide at a temperature higher than in the subsequent processes, it is possible to form a contact having low contact resistance and excellent thermal stability.

What is claimed is:

1. A method of fabricating a semiconductor device, comprising:
forming gate electrodes on a semiconductor substrate;
forming source/drain regions within the semiconductor substrate so as to be located at both sides of each of the gate electrodes;
forming a nickel silicide layer on surfaces of the gate electrodes and the source/drain regions;
forming an interlayer insulating layer, which is formed with contact holes through which a surface of the nickel silicide layer is exposed, on a surface obtained after the above processes have been performed;
forming an ohmic layer by evaporating a refractory metal conformably along the contact holes, the refractory metal being converted to silicide at a temperature of 500° C. or more;
forming a diffusion barrier on the ohmic layer conformably along the contact holes; and
forming a metal layer by burying a metal material within the contact holes.

2. The method of claim 1, wherein the forming of the nickel silicide layer includes:
evaporating nickel or nickel alloy on the semiconductor substrate formed with the gate electrodes and the source/drain regions, and
selectively removing the nickel or the nickel alloy which has not reacted after a thermal process so as to complete the nickel silicide layer.

3. The method of claim 2, wherein the forming of the nickel silicide layer further includes:
performing an additional thermal process on an entire surface of the nickel silicide layer at a temperature higher than the thermal process after the completion of the nickel silicide layer.

4. The method of claim 2, wherein the thermal process at the time of the forming of the nickel silicide layer is performed by using a rapid thermal process apparatus, a furnace, or a sputtering apparatus.

5. The method of claim 1, wherein the forming of the nickel silicide layer includes:
evaporating nickel or nickel alloy on the semiconductor substrate formed with the gate electrodes and the source/drain regions, and
selectively removing nickel or nickel alloy which has not reacted so as to complete the nickel silicide layer.

6. The method of claim 1, wherein the nickel alloy includes at least one selected from the group consisting of Ta, Zr, Ti, Hf, W, Co, Pt, Pd, V, Nb, and Re in an amount of 20 at % or less with respect to nickel.

7. The method of claim 1, wherein the ohmic layer is made of Ta, W, Hf, Mo, or V.

8. The method of claim 1, wherein the ohmic layer is formed by using a PVD method, a CVD method, or an ALD method.

9. The method of claim 1, wherein the diffusion barrier is made of TiN, TaN, or Wn.

10. The method of claim 1, wherein the metal layer is made of W, Cu, or Al.

11. A semiconductor device comprising:
gate electrodes formed on a semiconductor substrate;
source/drain regions formed within the semiconductor substrate so as to be located at both sides of each of the gate electrodes;
a nickel silicide layer formed on surfaces of the gate electrodes and the source/drain regions;
an interlayer insulating layer formed with contact holes through which a surface of the nickel silicide layer is exposed;
an ohmic layer which is formed conformably along the contact holes and is made of a refractory metal being converted to silicide at a temperature of 500° C. or more;
a diffusion barrier formed on the ohmic layer conformably along the contact holes; and
a metal layer buried within the contact holes.

12. The semiconductor device of claim 11, wherein the nickel silicide layer is formed by performing a thermal process on nickel or nickel alloy.

13. The semiconductor device of claim 11, wherein the nickel alloy includes at least one selected from the group consisting of Ta, Zr, Ti, Hf, W, Co, Pt, Pd, V, Nb, and Re in an amount of 20 at % or less with respect to nickel.

14. The semiconductor device of claim 11, wherein the ohmic layer is made of Ta, W, Hf, Mo, or V.

15. The semiconductor device of claim 11, wherein the diffusion barrier is made of TiN, TaN, or Wn.

16. The semiconductor device of claim 11, wherein the metal layer is made of W, Cu, or Al.

17. The method of claim 3, wherein the thermal process at the time of the forming of the nickel silicide layer is performed by using a rapid thermal process apparatus, a furnace, or a sputtering apparatus.

18. The method of claim 5, wherein the nickel alloy includes at least one selected from the group consisting of Ta, Zr, Ti, Hf, W, Co, Pt, Pd, V, Nb, and Re in an amount of 20 at % or less with respect to nickel.
